(19) United States
(12) Patent Application Publication
(10) Pub. No.: US 2013/0277784 A1
(43) Pub. Date: Oct. 24, 2013

(54) SOLAR ENERGY GATHERING DEVICE

(71) Applicant: PO-CHOU CHEN, Tu-Cheng (TW)

(72) Inventor: PO-CHOU CHEN, Tu-Cheng (TW)

(21) Appl. No.: 13/660,969

(22) Filed: Oct. 25, 2012

(30) Foreign Application Priority Data
Apr. 18, 2012 (TW) 101113783

(51) Int. Cl. H01L 31/052

(52) U.S. Cl. 257/432; 136/246; 257/E31.127

(57) ABSTRACT

A solar energy gathering device includes a number of light converging elements, an optical-electrical converting element, and a number of light guiding elements. The light converging elements receives sunlight. Each of the light converging elements has a focal point. The light guiding elements are corresponding to the light converging elements. Each of the light guiding elements has a first end and a second end opposite to the first end. Each of the first ends is positioned on the focal point of the corresponding light converging element to receive the sunlight from the corresponding light converging element. The second ends output the sunlight. The optical-electrical converting element receives the sunlight from the second ends, and converts solar energy of the sunlight from the second ends to electrical energy.

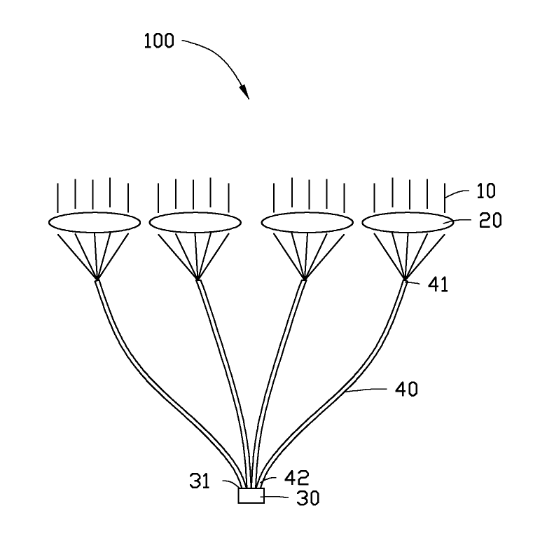

### BACKGROUND

1. Technical Field

The present disclosure relates to a solar energy gathering device.

2. Description of Related Art

Solar energy gathering devices are used for gathering solar energy to obtain electrical energy. Each of the solar energy gathering devices includes only one light converging element and only one optical-electrical converting element, such as a solar panel. The optical-electrical converting element is positioned on a focal point of the light converging element. For gathering more solar energy, a larger area of light converging element is needed, therefore, the focal length of the light converging element becomes longer, and the distance between the light converging element and the optical-electrical converting element becomes longer, which will increase the volume of the solar energy gathering device.

Therefore, it is desirable to provide a solar energy gathering device that can overcome the above-mentioned limitations.

### BRIEF DESCRIPTION OF THE DRAWINGS

Many aspects of the embodiments should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

The FIGURE is a schematic view of a solar energy gathering device, according to an exemplary embodiment.

### DETAILED DESCRIPTION

The FIGURE illustrates a solar energy gathering device 100 in accordance to an embodiment. The solar energy gathering device 100 includes a number of light converging elements 20, a number of light guiding elements 40, and an optical-electrical converting element 30.

The light converging elements 20 are used for converging sunlight 10. Each of the light converging elements 20 has a focal point. In this embodiment, the light converging elements 20 are converging lenses, such as convex lenses, Fresnel lenses, or compound parabolic concentrators (CPC).

The light guiding elements 40 are corresponding to the light converging elements 20, and are used for guiding the sunlight 10 from the corresponding light converging elements 20 to the optical-electrical converting element 30. Each of the light guiding elements 40 has a first end 41 and a second end 42 opposite to the first end 41. Each of the first ends 41 is positioned on the focal point of the corresponding light converging element 20 to receive the sunlight 10 from the corresponding light converging element 20. Each of the second ends 42 is used for outputting the sunlight 10 from the corresponding light converging element 20. In this embodiment, the light guiding elements 40 are optical fibers.

The optical-electrical converting element 30 is used for converting solar energy of the sunlight 10 to electrical energy. The optical-electrical converting element 30 has a light receiving surface 31 for receiving the sunlight 10 from the second ends 42. In this embodiment, the optical-electrical converging element 30 is a solar panel or a photo diode, and the second ends 42 is in contact with the light receiving surface 31. In other embodiment, the second ends 42 also can be spaced from the light receiving surface 31.

In use, the light converging elements 20 converge the sunlight 10, the first ends 41 receive the sunlight 10 from the corresponding light converging elements 20, the light guide elements 40 transmit the sunlight 10, and the second ends 42 output the sunlight 10 to the light receiving surface 31, the optical-electrical converting element 30 converts solar energy of the sunlight 10 to electrical energy.

By employing the solar energy gathering device 100, the light converging elements 20 can receive more sunlight, and thus the solar energy gathering device 100 can generate more electrical energy. At the same time, the area of each of the light converging elements 20 does not need to become larger, therefore, the focal length of the light converging element 20 does not need to become longer, and the distance between the light converging element 20 and the light guide elements 40 does not need to become longer, the volume of the solar energy gathering device 100 does not need to become larger.

In this embodiment, the number of the light guiding elements 40 is substantially equal to the number of the light converging elements 20. In other embodiment, the number of the light guiding elements 40 also can be greater than the number of the light converging elements 20.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A solar energy gathering device, comprising:
a plurality of light converging elements configured for receiving sunlight, wherein each of the light converging elements has a focal point;
a plurality of light guiding elements, each of the light guiding elements corresponding to a respective one of the light converging elements, wherein each of the light guiding elements has a first end and a second end opposite to the first end, each of the first ends is positioned on the focal point of the corresponding light converging element to receive the sunlight from the corresponding light converging element, the second ends are configured for outputting the sunlight; and
an optical-electrical converting element configured for receiving the sunlight from the second ends, and converting solar energy of the sunlight from the second ends to electrical energy.

2. The solar energy gathering device of claim 1, wherein each of the light converging elements is a convex mirror, an Fresnel lens, or a compound parabolic concentrator.

3. The solar energy gathering device of claim 1, wherein the optical-electrical converting element is a solar panel or a photo diode.

4. The solar energy gathering device of claim 1, wherein the optical-electrical converting element has a light receiving surface for receiving the sunlight.

5. The solar energy gathering device of claim 4, wherein each of the second ends is in contact with the light receiving surface.

6. The solar energy gathering device of claim 4, wherein each of the second ends is spaced from the light receiving surface.

7. The solar energy gathering device of claim 1, wherein the light guiding elements are optical fibers.
